(19) United States
(12) Patent Application Publication
(10) Pub. No.: US 2005/0260847 A1
(43) Pub. Date: Nov. 24, 2005

(54) Method for forming contact window

(76) Inventors: J. H. Yang, Tainan (TW); Shih Fan Kuan, Taoyuan (TW); Kuo Chien Wu, Miaoli (TW)

Correspondence Address: BIRCH STEWART KOLASCH & BIRCH, PO BOX 747, FALLS CHURCH, VA, 22040-0747, US

(21) Appl. No.: 10/851,147

(22) Filed: May 24, 2004

(51) Int. Cl. H01L 21/00

(52) U.S. Cl. 438/637; 438/597; 438/618; 438/622

(57) ABSTRACT

A method for forming a contact window is provided. First, a substrate is provided. On the substrate a dielectric layer is formed. Then, the dielectric layer is etched to form an opening, which defines a sidewall. Afterwards, on the sidewalls a low leakage dielectric isolation layer is formed. Finally, a contact window is formed by etching the substrate through the opening.

### FIELD OF INVENTION

The present invention relates to a method for forming a contact window.

### BACKGROUND OF THE INVENTION

In the manufacturing process of integrated circuits, it is often required to form contact windows for electrical connection after most of the main elements have been formed on the substrate. One of the conventional methods for forming the contact windows is shown in FIG. 1a to 1d. A cap nitride layer 102 is formed on a substrate 100, on which a plurality of elements 101 have been previously formed. Then an isolation layer 103, which is usually made of BPSG, is formed thereon. Another isolation layer 104, which is usually made of TEOS, is formed on isolation layer 103. A photoresist 105 defining a contact window pattern 106 is formed on isolation layer 104. Afterwards, with the photoresist 105 serving as a mask, the exposed isolation layer 104 is first etched, then, isolation layer 103 and cap nitride layer 102 are etched consecutively until the desired contact window 107 is formed.

As more and more elements are integrated on the substrate, the size of the pattern 106 is getting smaller and smaller. Consequently, the vertical anisotropy of the etched space, i.e. the contact window, gets higher and higher. In other words, it inevitably increases the “aspect ratio.”

High aspect ratio raises the risk of over-etching, which in turn increases the risk of exposing and short-circuiting the elements 101 on substrate 100. In addition, the shoulders of the elements are apt to be damaged, which results in defects 108. Therefore, there is a need for an alternative solution for forming contact windows.

### SUMMARY OF THE INVENTION

One of the main aspects of the present invention provides a method for forming a contact window. A low leakage dielectric isolation layer is formed on the sidewalls of previously formed openings to prevent the elements on the substrate from short-circuits due to over-etching.

Another aspect of the present invention provides a method for forming a contact window. A low leakage dielectric isolation layer is formed on the sidewalls of previously formed openings to prevent the shoulders of the elements on the substrate from being damaged due to over-etching.

The present invention therefore discloses a method for forming a contact window, comprising the steps of:
(a) providing a substrate;
(b) forming an isolation layer on the substrate;
(c) etching the isolation layer to form an opening defining a sidewall;
(d) forming a low leakage dielectric isolation layer on the sidewall; and
(e) etching the substrate through the opening to form a contact window.

### BRIEF DESCRIPTION OF THE DRAWINGS

FIGS. 1a to 1d illustrate conventional steps of prior art;

FIGS. 2a to 2f illustrate a preferred embodiment of the present invention.

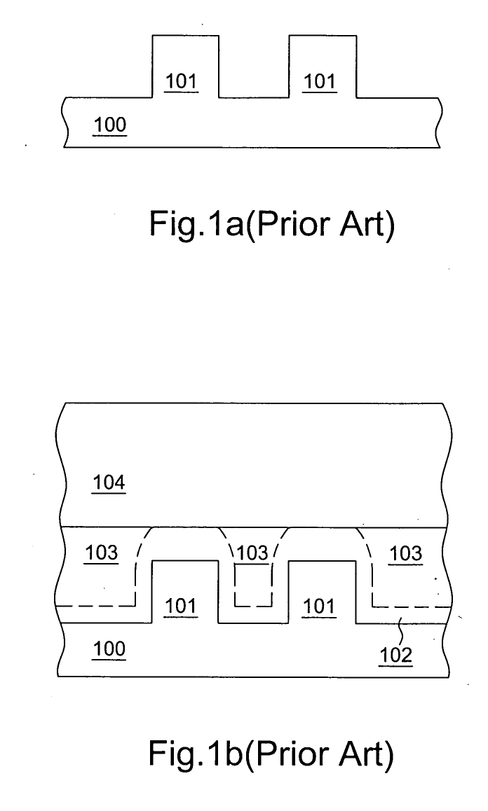

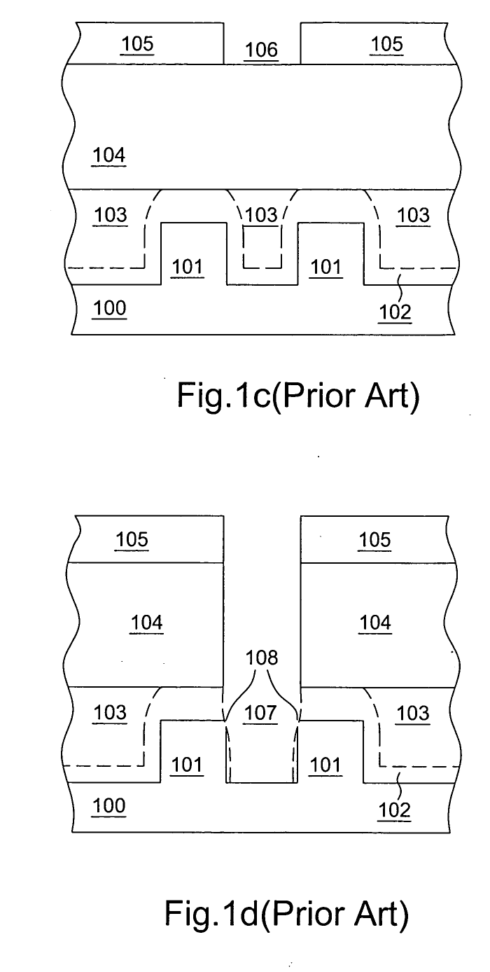

### DETAILED DESCRIPTION

The present invention generally relates to a method of forming contact windows on a substrate. These and other aspects, features, and advantages of the present invention will become apparent from the following detailed description of illustrative embodiments thereof, which is to be read in connection with the accompanying drawings. It should be understood, however, that the scope of the present invention is not limited by the illustration of the examples.

The elements on the substrate can be formed via various methods, such as deposition, chemical vapor deposition or atomic layer deposition (ALD), which are known to persons skilled in the art. In addition, Chemical Mechanical Planarization (CMP) may be employed to carry out possible planarization step(s).

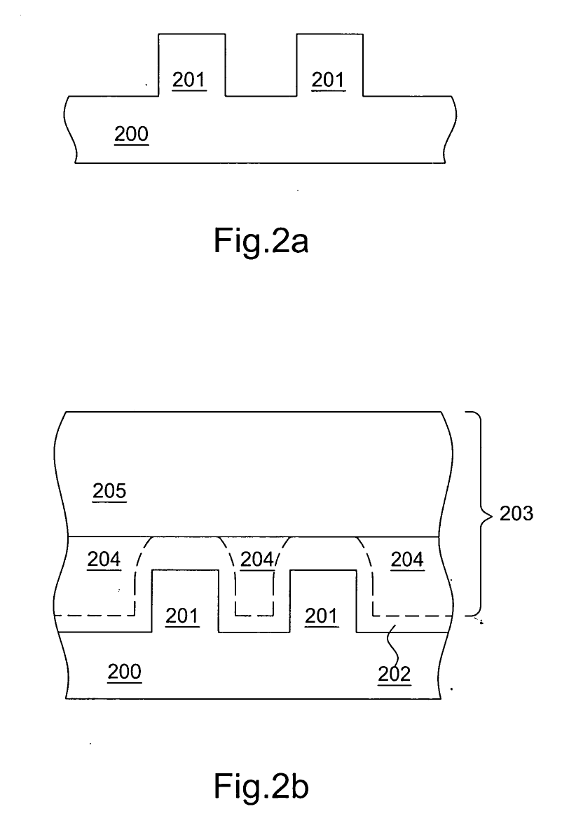

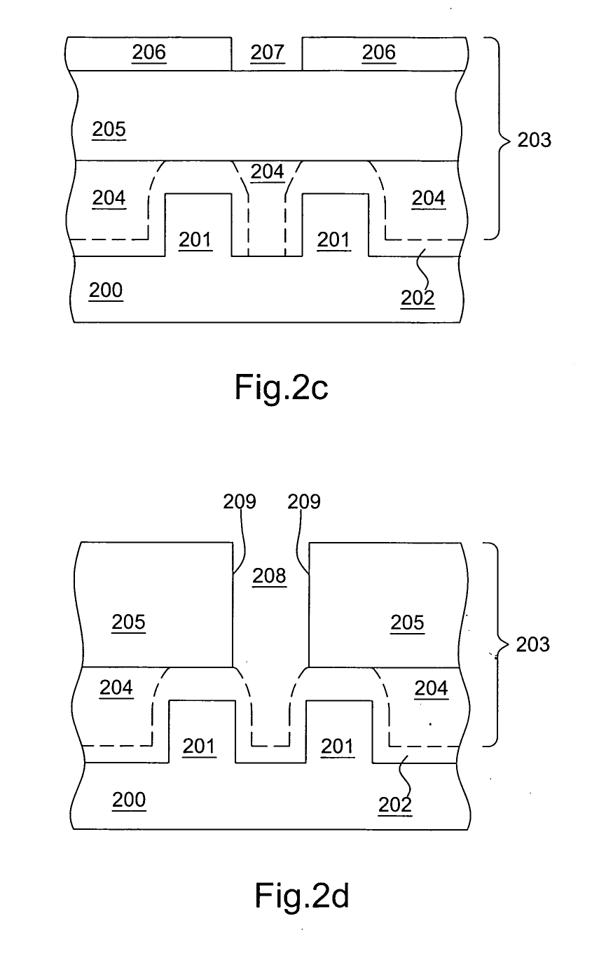

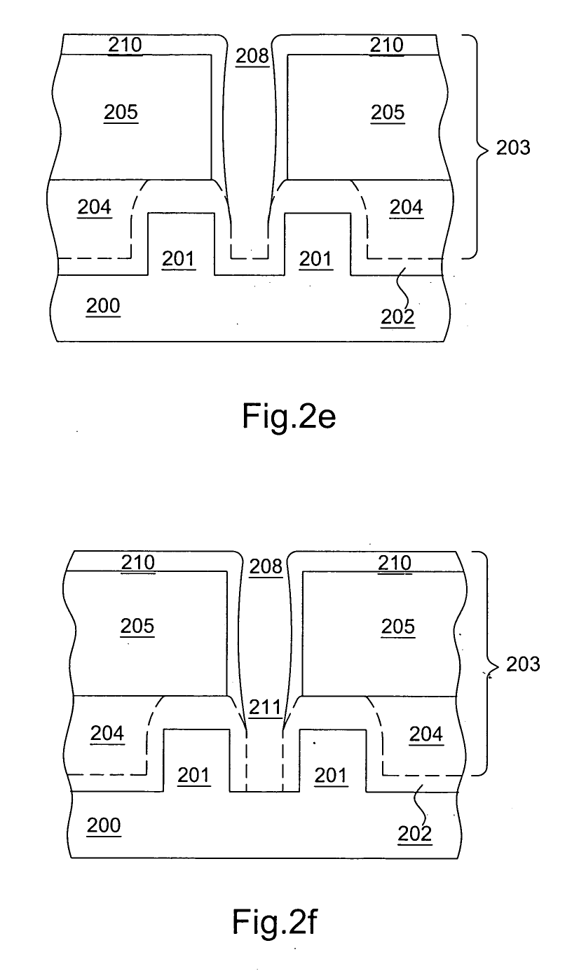

A preferred embodiment of the present invention is illustrated in FIGS. 2a to 2f. Please refer to FIG. 2a. Substrate 200 is provided and a plurality of elements 201, control gates for example, are formed thereon. Substrate 200 is preferably made of silicon, more preferably doped silicon. Elements 201 may be formed on or in substrate 200 by methods known to those skilled in the art. To make the descriptions concise, some of the elements and/or layers may be simplified or partially/entirely ignored since they are well known to those skilled in the art. For instance, on or in substrate 200 may be one or more previously formed regions or layers. A pair of elements 201 here would stand for all possible elements.

Please refer to FIG. 2b. A layer of cap nitride 202, which typically consists of silicon nitride, may optionally be formed on substrate 200 having a plurality of elements 201. Then an isolation layer 203 is formed. The isolation layer 203 usually includes a plurality of layers. The layers may include a layer of silicon oxide 204 such as one made of BPSG, an isolation layer 205 such as one made of TEOS, or the combination thereof. When cap nitride layer 202 does exist, isolation layer 203 is formed on cap nitride layer 202, as shown in FIG. 2b. If there is no cap nitride layer 202, isolation layer 203 is directly formed on substrate 200. Planarization may be carried out after desired layers have been formed.

Please refer to FIG. 2c. A photoresist 206 defining a contact window pattern 207 is formed on isolation layer 205. Using photoresist 206 as a mask, insulation layer 203 is etched to form an opening 208 as shown in FIG. 2d. After etching, photoresist 206 is removed. Opening 208 defines sidewall 209 and exposes cap nitride layer 202. Subsequently, shown in FIG. 2e, a low leakage dielectric isolation layer 210 is formed on sidewalls 209 shown in FIG. 2d by means of non-conformal deposition. The low leakage dielectric isolation layer 210 may include an aluminum oxide. The aluminum oxide is an oxygen-rich aluminum oxide, for example, an aluminum oxide with an O/Al ratio of about 2.5 to about 4.

Finally, please refer to FIG. 2f, cap nitride layer 202 can be further etched through opening 208 until substrate 200 is accordingly exposed. The desired contact window 211 is then formed.

As stated above, by means of the steps illustrated in FIGS. 2a to 2f, contact window 211 is formed on substrate 200.

By means of the detailed descriptions of what is presently considered to be the most practical and preferred embodiments of the subject invention, it is the expectation that the features and the gist thereof are plainly revealed. Nevertheless, these above-mentioned illustrations are not intended to be construed in a limiting sense. Instead, it should be well understood that any analogous variation and equivalent arrangement is supposed to be covered within the spirit and scope to be protected and that the interpretation of the scope of the subject invention would therefore as much as broadly apply.

1. A method for forming a contact window, comprising the steps of:
(a) providing a substrate;
(b) forming an isolation layer on said substrate;
(c) etching said isolation layer to form an opening defining a sidewall;
(d) forming a low leakage dielectric isolation layer on said sidewall; and
(e) etching said substrate through said opening to form a contact window.

2. The method of claim 1, wherein said step (a) further comprises a step of:
(f) forming a nitride layer on said substrate.

3. The method of claim 2, wherein said nitride layer is exposed in said step (c).

4. The method of claim 1, wherein said isolation layer comprises a plurality of layers.

5. The method of claim 4, wherein said layers comprise a BPSG layer, a TEOS layer or a combination thereof.

6. The method of claim 1, wherein said low leakage dielectric isolation layer is formed by a non-conformal deposition method.

7. The method of claim 1, wherein said low leakage dielectric isolation layer comprises an oxygen-rich aluminum oxide.

8. The method of claim 7, wherein said oxygen-rich aluminum oxide has an O/Al ratio ranging from about 2.5 to about 4.

9. A method for forming a contact window, comprising the steps of:
(a) providing a substrate;
(b) forming a nitride layer on said substrate;
(c) forming an isolation layer on said nitride layer;
(d) etching said isolation layer to form an opening exposing said nitride layer, said opening defining a sidewall;
(e) forming a low leakage dielectric isolation layer on said sidewall by a non-conformal deposition method, wherein said low leakage dielectric isolation layer comprises an oxygen-rich aluminum oxide; and
(e) etching said substrate through said opening to form a contact window.

10. The method of claim 9, wherein said isolation layer comprises a plurality of layers.

11. The method of claim 10, wherein said layers comprise a BPSG layer, a TEOS layer or a combination thereof.

12. The method of claim 9, wherein said oxygen-rich aluminum oxide has an O/Al ratio ranging from about 2.5 to about 4.
